(19) United States
(12) Patent Application Publication
(10) Pub. No.: US 2010/0288535 A1
(43) Pub. Date: Nov. 18, 2010

(54) ELECTRONIC COMPONENT-EMBEDDED PRINTED CIRCUIT BOARD COMPRISING COOLING MEMBER AND METHOD OF MANUFACTURING THE SAME

(76) Inventors: Suk Chang HONG, Chungcheongbuk-do (KR); Kwang Seop Youm, Chungcheongbuk-do (KR); Bong Kyu Choi, Chungcheongbuk-do (KR)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 12/546,502

(22) Filed: Aug. 24, 2009

(30) Foreign Application Priority Data
May 15, 2009 (KR) 10-2009-0042610

(51) Int. Cl. H05K 1/02; H05K 3/30

(52) U.S. Cl. 174/252; 29/832

(57) ABSTRACT

Disclosed herein is an electronic component-embedded printed circuit board, in which a cooling member connecting with an inner circuit layer of a printed circuit board is provided on one side of an electronic component, so that the heat radiation performance thereof can be improved and the thickness thereof can be decreased, and a method of manufacturing the same.

### CROSS REFERENCE TO RELATED APPLICATION

This application claims the benefit of Korean Patent Application No. 10-2009-0042610, filed May 15, 2009, entitled “Printed circuit board with electronic components embedded therein including cooling member and method for fabricating the same”, which is hereby incorporated by reference in its entirety into this application.

### BACKGROUND OF THE INVENTION

1. Technical Field

The present invention relates to an electronic component-embedded printed circuit board comprising a cooling member and a method of manufacturing the same.

2. Description of the Related Art

Recently, since electronic appliances are being smaller and lighter, the development of a printed circuit board embedded with an electronic component such as a semiconductor device or the like has attracted considerable attention.

In order to realize an electronic component-embedded printed circuit board, many surface mounting technologies for mounting a semiconductor chip such as an integrated circuit (IC) chip or the like on a printed circuit board are available. Wire bonding, flip chip and the like are examples of such surface mounting technologies.

Here, in the surface mounting method using wire bonding, an electronic component is bonded on a printed circuit board using an adhesive, and a lead frame of the printed circuit board is connected with metallic terminals (that is, pads) of the electronic component through a metal wire in order to transmit and receive information therebetween, and then the electronic component and the metal wire are molded using a thermosetting or thermoplastic resin.

Further, in the surface mounting method using a flip chip method, external connection terminals (that is, bumps) of several tens of micrometers to several hundreds of micrometers are formed on an electronic component using gold, solder and other metals, and, in opposition to the surface mounting method using wire bonding, the electronic component formed thereon with bumps is turned over to mount the electronic component on a printed circuit board such that the surface of the electronic component faces the printed circuit board.

However, in these surface mounting methods, since an electronic component is mounted on the surface of a printed circuit board, the total thickness of the printed circuit board mounted thereon with the electronic component cannot be smaller than the sum of the thickness of the printed circuit board and the thickness of the electronic component, and thus it is difficult to manufacture a highly-densified printed circuit board. Further, in these surface mounting methods, since an electronic component is electrically connected with a printed circuit board through connection terminals (pads or bumps), the connection terminals can be cut and corroded, so that the electrical connection between the electronic component and the printed circuit board fails and a malfunction occurs, thereby deteriorating reliability.

Therefore, it is required that an electronic component be electrically connected with a printed circuit board by mounting the electronic component inside the printed circuit board, not outside the printed circuit board, and then forming a build-up layer thereon, that the distance between wirings is minimized, and that the reliability problems occurring when the electronic component is connected to the printed circuit board through a surface mounting method using wire bond or flip chip are improved upon.

FIGS. 1 to 7 are sectional views showing a conventional method of manufacturing an electronic component-embedded printed circuit board in which the electronic component is mounted inside the printed circuit board. The method of manufacturing an electronic component-embedded printed circuit board is described with reference to FIGS. 1 to 7 as follows.

First, as shown in FIG. 1, a core layer 10, which is composed of a copper clad laminate (CCL) in which an inner circuit layer 11 and a cavity 12 for mounting an electronic component are formed, is prepared.

Subsequently, as shown in FIG. 2, a tape 13 for supporting the electronic component is adhered to one side of the core layer 10.

Subsequently, as shown in FIG. 3, the electronic component 14 provided thereon with pads 15 is adhered to the tape 13 in a face-up state such that the electronic component is mounted in the cavity 12.

Subsequently, as shown in FIG. 4, a first outer insulation layer is formed on the other side of the core layer 10 to which the tape 13 is not adhered and in the space between the electronic component and the cavity 12, and is then cured.

Subsequently, as shown in FIG. 5, the tape 13 adhering to one side of the core layer 10 is removed.

Subsequently, as shown in FIG. 6, a second outer insulation layer 17 is formed on the one side of the core layer 10 from which the tape was removed.

Finally, as shown in FIG. 7, an outer circuit layer 18 having vias connected with the inner circuit layer 11 or the pads 15 of the electronic component 14 is formed on the first outer insulation layer 16 and the second outer insulation layer 17 to manufacture a conventional electronic component-embedded printed circuit board 20.

However, the conventional electronic component-embedded printed circuit board 20 manufactured in this way is problematic in that the heat generated from the electronic component 14 is radiated to the outside through the vias 19 serving as interlayer signal passages, so that it is difficult to radiate the heat generated from the inner and outer circuit layers 11 and 18 and the heat generated from the electronic component 14 due to the long operation time of the electronic component 14 to the outside through only vias 19, with the result that the lifespan of the electronic component is shortened and the performance of the electronic component-embedded printed circuit board 20 is deteriorated.

In particular, when the electronic component-embedded printed circuit board 20 shown in FIG. 7 is provided with a multilayered build-up layer, it is much more difficult to radiate the heat generated from the inner and outer circuit layers 11 and 18 and the electronic component 14 to the outside through only the vias 19.

### SUMMARY OF THE INVENTION

Accordingly, the present invention has been made to solve the above-mentioned problems, and the present invention provides an electronic component-embedded printed circuit board having improved heat radiation performance, which is provided with a cooling member, and a method of manufacturing the same.

An aspect of the present invention provides an electronic component-embedded printed circuit board, including: a core substrate in which a cavity is formed, and of which inner circuit layers are formed; an electronic component which is mounted in the cavity and is provided on one side thereof with pads; a cooling member which is adhered to the other side of the electronic component through a conductive material and is connected to the inner circuit layers; and outer insulation layers which are formed on both sides of the core substrate to cover the electronic component.

Here, outer circuit layers connecting with the pads or the inner circuit layers through vias may be formed on the outer insulation layers.

Further, the electronic component may be formed on the other side thereof with ground pads, and the ground pads may be connected with the cooling member through the conductive material.

Further, the inner circuit layers connected with the cooling member may serve as ground layers.

Further, the conductive material may be a conductive paste or a conductive adhesive.

Another aspect of the present invention provides a method of manufacturing an electronic component-embedded printed circuit board, including: fabricating a core substrate provided with a cavity and inner circuit layers and then adhering a tape to one side of the core substrate; adhering an electronic component provided on one side thereof with pads onto the tape such that the electronic component is mounted in the cavity so as to face-up; forming a first outer insulation layer on the other side of the core substrate including the space between the electronic component and the cavity and then removing the tape; and adhering a cooling member connecting with the inner circuit layers onto the other side of the electronic component using a conductive material and then forming a second outer insulation layer on the other side of the core substrate provided with the cooling member.

Here, the method may further include: forming outer circuit layers connecting with the inner circuit layers or the pads through vias on the first outer insulation layer and the second outer insulation layer, after the forming of the second outer insulation layer.

Further, the electronic component may be formed on the other side thereof with ground pads, and the ground pads may be connected with the cooling member through the conductive material.

Further, the inner circuit layers connected with the cooling member may serve as ground layers.

Further, the conductive material may be a conductive paste or a conductive adhesive.

Still another aspect of the present invention provides a method of manufacturing an electronic component-embedded printed circuit board, including: fabricating a core substrate provided with a cavity and inner circuit layers and then adhering a tape to one side of the core substrate; adhering an electronic component provided on one side thereof with pads onto the tape such that the electronic component is mounted in the cavity so as to face-down; adhering a cooling member connecting with the inner circuit layers onto the other side of the electronic component using a conductive material and then forming a first outer insulation layer on one side of the core substrate provided with the cooling member; and removing the tape and then forming a second outer insulation layer on the other side of the core substrate including the space between the electronic component and the cavity.

Here, the method may further include: forming outer circuit layers connecting with the inner circuit layers or the pads through vias on the first outer insulation layer and the second outer insulation layer, after the forming of the second outer insulation layer.

Further, the electronic component may be formed on the other side thereof with ground pads, and the ground pads may be connected with the cooling member through the conductive material.

Further, the inner circuit layers connected with the cooling member may serve as ground layers.

Further, the conductive material may be a conductive paste or a conductive adhesive.

Still another aspect of the present invention provides a method of manufacturing an electronic component-embedded printed circuit board, including: fabricating a core substrate provided with a cavity and inner circuit layers and then adhering a cooling member to the inner circuit layer of one side of the core substrate to cover the cavity; placing an electronic component provided on one side thereof with pads onto the cooling member such that the electronic component is mounted in the cavity so as to face-up; and forming outer insulation layers on both sides of the core substrate including the space between the electronic component and the cavity.

Here, the cooling member may be formed therein with holes in order to prevent a void trap from occurring when the outer insulation layers are formed.

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

### BRIEF DESCRIPTION OF THE DRAWINGS

The above and other objects, features and advantages of the present invention will be more clearly understood from the following detailed description taken in conjunction with the accompanying drawings, in which:

FIGS. 1 to 7 are sectional views showing a conventional method of manufacturing an electronic component-embedded printed circuit board;

FIG. 8 is a sectional view showing an electronic component-embedded printed circuit board comprising a cooling member according to a first embodiment of the present invention;

FIG. 9 is a sectional view showing an electronic component-embedded printed circuit board comprising a cooling member according to a second embodiment of the present invention;

FIGS. 10 to 18 are sectional views showing a method of manufacturing an electronic component-embedded printed circuit board comprising a cooling member according to a first embodiment of the present invention;

FIGS. 19 to 26 are sectional views showing a method of manufacturing an electronic component-embedded printed circuit board comprising a cooling member according to a second embodiment of the present invention; and

FIGS. 27 to 32 are sectional views showing a method of manufacturing an electronic component-embedded printed circuit board comprising a cooling member according to a third embodiment of the present invention.

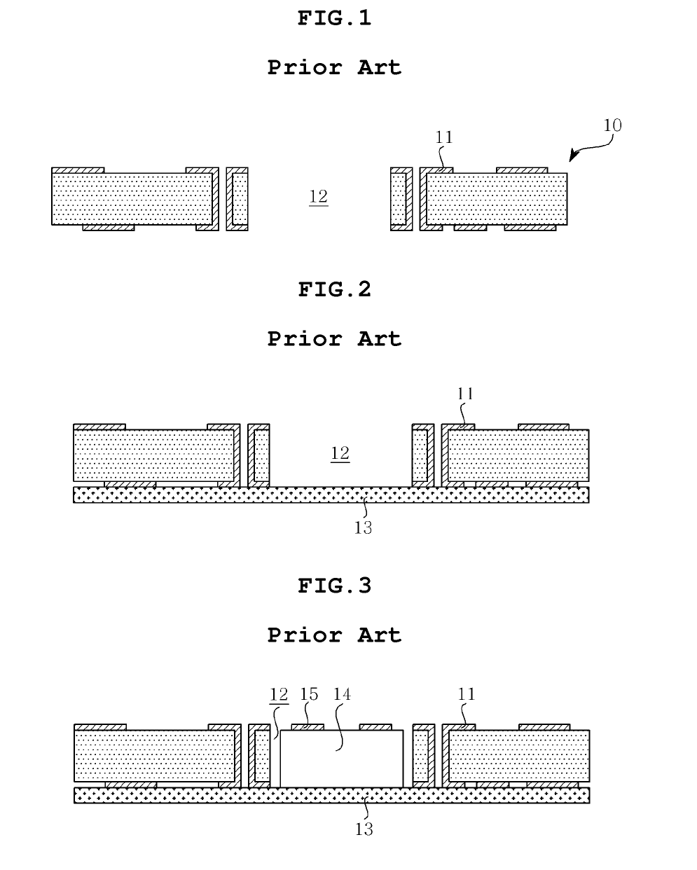

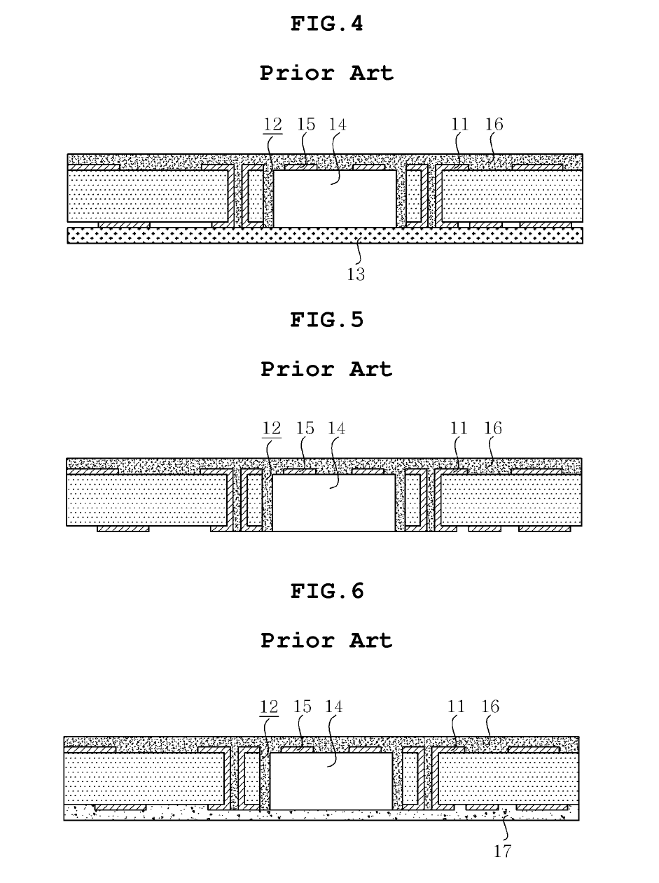

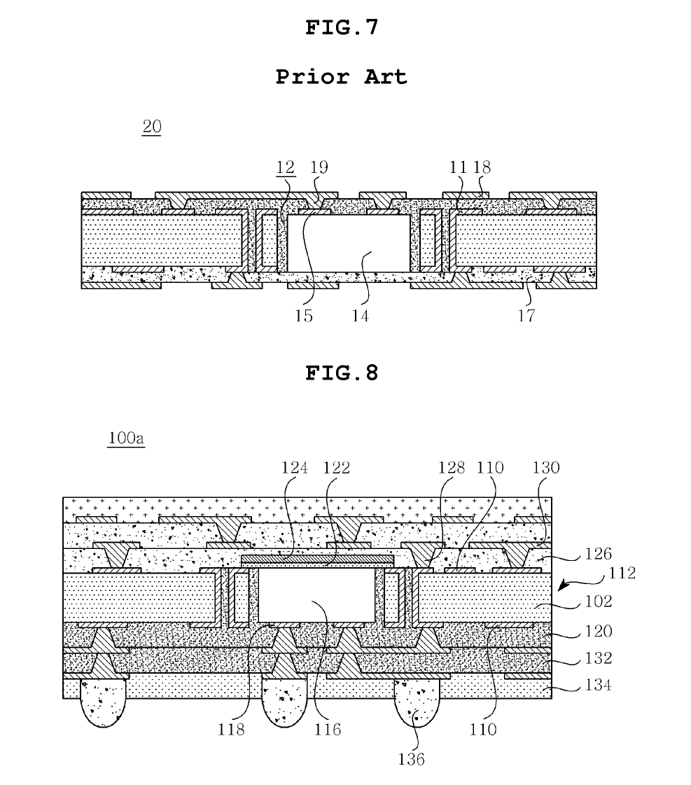

### DESCRIPTION OF THE PREFERRED EMBODIMENTS

The objects, features and advantages of the present invention will be more clearly understood from the following detailed description and preferred embodiments taken in conjunction with the accompanying drawings. Throughout the accompanying drawings, the same reference numerals are used to designate the same or similar components, and redundant descriptions thereof are omitted. In the description of the present invention, when it is determined that the detailed description of the related art obscure the gist of the present invention, the description thereof will be omitted.

Hereinafter, preferred embodiments of the present invention will be described in detail with reference to the attached drawings.

FIG. 8 is a sectional view showing an electronic component-embedded printed circuit board provided with a cooling member according to a first embodiment of the present invention. Hereinafter, the electronic component-embedded printed circuit board 100a provided with a cooling member according to a first embodiment of the present invention will be described with reference to FIG. 8.

As shown in FIG. 8, the electronic component-embedded printed circuit board 100a according to a first embodiment of the present invention includes a core substrate 112, an electronic component 116, a cooling member 124, and outer insulation layers 120 and 126.

The core substrate 112 includes through-holes 108 for forming an interlayer connection between inner circuit layers 110, a cavity 106 for mounting the electronic component, and inner circuit layers 110, including circuit patterns and lands, formed on both sides of the core substrate 112. Here, the inner circuit layers 110 serves as ground layers as well as patterning parts. Further, the inner circuit layers 110 serve to improve the heat radiation performance of the printed circuit board because it is connected to the cooling member 124 adhered to the other side of the electronic component 116.

The electronic component 116, which is a semiconductor device, is provided on one side thereof with pads 118.

The cooling member 124 serves to radiate the heat generated by the operation of the electronic compound 116, and is made of a high-conductivity metal. Here, a heat pipe is used as the cooling member 124, and the cooling member 124 is adhered to the other side of the electronic compound 116 by a conductive material 122. In this case, any materials can be employed as the conductive material 122 as long as they enable the cooling member 124 to be adhered and fixed onto the other side of the electronic component and enable the heat generated from the electronic component to be transferred to the cooling member 124. For example, conductive paste or conductive adhesive can be used as the conductive material. Further, since the cooling member 124 is connected with the inner circuit layer 110, it serves to accomplish the heat radiation function of the cooling member 124 itself and simultaneously to increase heat radiation efficiency by transferring the heat generated from the electronic component to the inner circuit layer. It is preferred that the cooling member 124 be formed therein with holes in order to prevent the void trap occurring when outer insulation layers are formed.

The outer insulation layers 120 and 126 are formed on both sides of the core substrate 112, and support the electronic component. Here, outer circuit layers 130 are formed on the outer insulation layers 120 and 126, and vias 128 for connecting the inner circuit layers 110 or pads 118 with the outer circuit layers 30 are formed in the outer insulation layers 120 and 126.

Meanwhile, in the electronic component-embedded printed circuit board 100a according to this embodiment of the present invention, a build-up layer 132 including insulation layers and circuit layers may be formed, a solder resist layer 134 for protecting the circuit layers may be formed on the outermost layer of the build-up layer 132, and solder balls 136 connecting with external appliances may be provided in the solder resist layer 134.

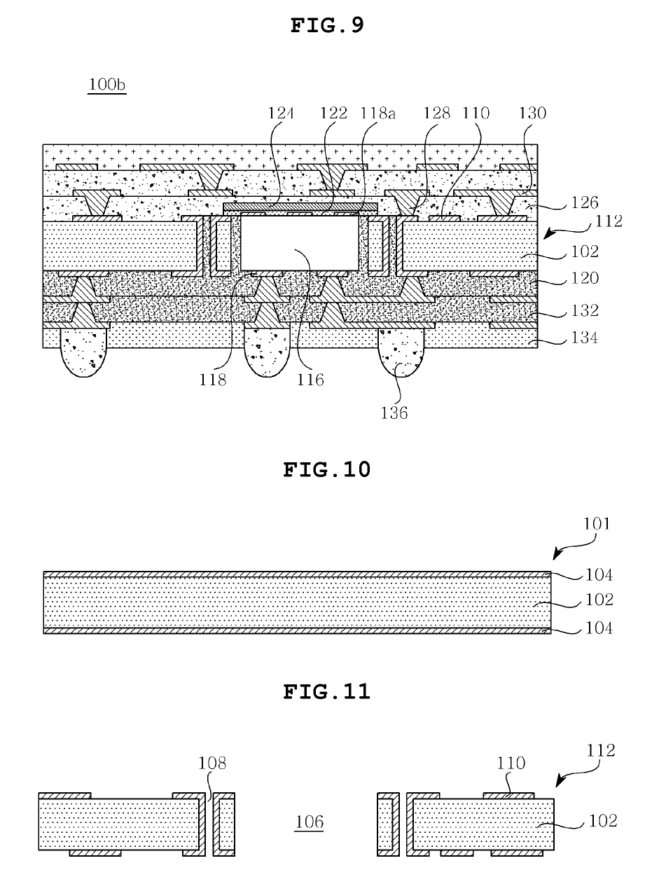

FIG. 9 is a sectional view showing an electronic component-embedded printed circuit board provided with a cooling member according to a second embodiment of the present invention. Hereinafter, the electronic component-embedded printed circuit board 100b provided with a cooling member according to a second embodiment of the present invention will be described with reference to FIG. 9.

As shown in FIG. 9, the electronic component-embedded printed circuit board 100b according to this embodiment of the present invention has the same structure as the electronic component-embedded printed circuit board 100a according to the first embodiment of the present invention, except that, among the total pads formed on the electronic component 116, pads 118 connecting with the printed circuit board are formed on one side of the electronic component 116, and ground pads 118a connecting with ground are formed on the other side of the electronic component 116.

That is, the ground pads 118a formed on the other side of the electronic component 116 are connected to the cooling member 124 through the conductive material, and are connected to an inner circuit layer 110, functioning as a ground layer, which is connected to the cooling member 124.

According to the above structured electronic component-embedded printed circuit board 100b, heat radiation performance is improved, vias for connecting the ground pads 118 with the inner circuit layer 110 are not additionally required, and only vias 128 for connecting the pads of the electronic component with the outer circuit layer 130 are required, thereby increasing the densification of the printed circuit board.

FIGS. 10 to 18 are sectional views showing a method of manufacturing an electronic component-embedded printed circuit board provided with a cooling member according to a first embodiment of the present invention. Hereinafter, this method of manufacturing an electronic component-embedded printed circuit board will be described with reference to FIGS. 10 to 18 as follows. In this embodiment, the electronic component-embedded printed circuit board shown in FIG. 8 is manufactured by mounting an electronic component in a printed circuit board so that it faces up.

First, as shown in FIG. 10, a base substrate 101, which is composed of a copper clad laminate (CCL) in which an insulation layer 102 is coated on both sides thereof with copper foil 104, is provided.

Subsequently, as shown in FIG. 11, a core substrate 112 is fabricated by forming a cavity 106 and through-holes 108 in the base substrate 101 and then forming inner circuit layers 110 thereon.

In this case, the through-holes 108 for interlayer connection and the cavity 106 for inserting an electronic component are formed in the base substrate 101 using a computer numerical controlled (CNC) drill or a laser drill (CO₂ laser drill or Nd-YAG laser drill), and a copper plating layer (electroless or electrolytic copper plating layer) is formed on the inner walls of the through-holes 108 and on the copper foil 104 through a plating process. Subsequently, a photoresist is applied on the copper plating layer, a photo mask comes closely thereto, and then patterns are formed on the photoresist through exposure/development using UV. Thereafter, unnecessary copper plating and copper foil are etched and thus removed through a chemical reaction using the patterned photoresist as an etching resist, and then the photoresist is removed, thereby forming the inner circuit layers 110.

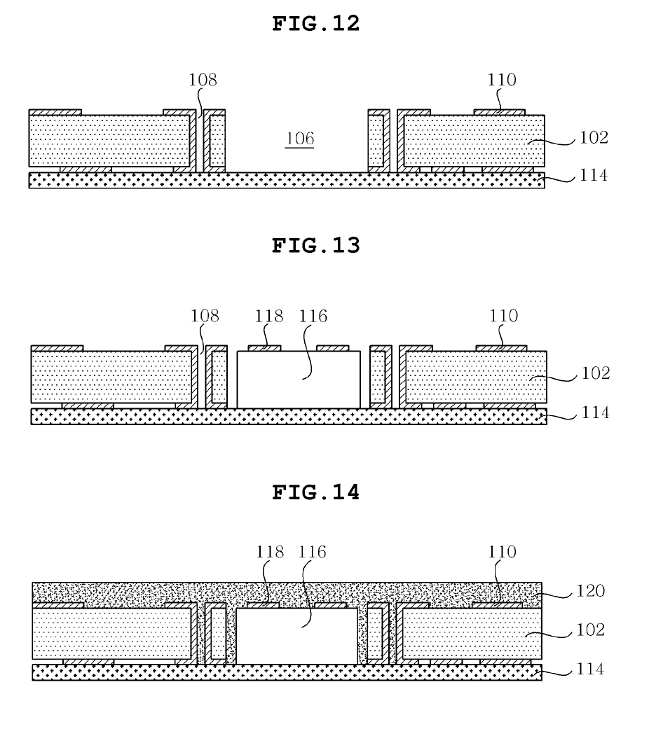

Subsequently, as shown in FIG. 12, a tape 114 for supporting an electronic component is adhered to one side of the core substrate 112.

In this case, as the tape 114, a silicon rubber tape or a polyimide (PI) adhesive tape may be used. An electronic component can be positioned at a desired place using the silicon rubber tape or polyimide (PI) adhesive tape. Further, it is preferred that this tape 114 have heat resistance such that it is not deformed by heating or pressurization in a subsequent process of mounting an electronic component in a printed circuit board and then charging a filler therein and then curing the filler to protect the electronic component or a subsequent process of forming an insulation layer.

Subsequently, as shown in FIG. 13, an electronic component 116 is adhered to the tape 114 formed one side of the core substrate 112 such that the electronic component 116 is mounted in the cavity 106.

In this case, the electronic component 116 is adhered to the predetermined position of the tape 114. The electronic component 116 is mounted so as to face-up such that pads, which are electrically connected with circuit layers and are formed on one side of the electronic component 116, face upward. Here, ground pads 118a (refer to FIG. 9) may be formed on the other side of the electronic component 116.

Subsequently, as shown in FIG. 14, a first outer insulation layer 120 is formed on the other side of the core substrate 112 to which the tape 114 was not adhered, including the space between the electronic component 116 and the cavity 106.

In this case, the first outer insulation layer 120 is formed on the other side of the core substrate 112 including the space between the electronic component 116 and the cavity 106 and the through-holes 108 by pressurizing a semi-cured insulation layer, for example, a prepreg.

Meanwhile, in this step, an encapsulation process may be previously performed in order to stick the electronic component 116 onto the tape 114 and then fix the electronic component 116. The encapsulation process is a process of charging a filler (not shown) into the space between the cavity 106 and the electronic component 116 such that the electronic component does not move and can be fixed at a predetermined position. Here, the charging of the filler can be performed through a screen printing method, a mask printing method, a dispensing method or the like, and the filler may be a thermosetting resin, a thermoplastic resin or a complex thereof.

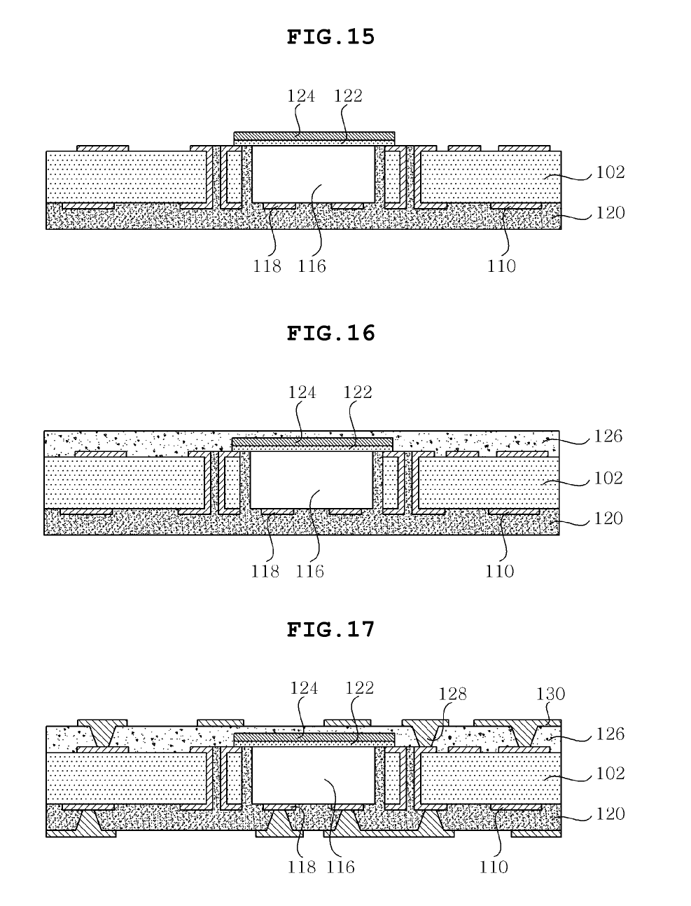

Subsequently, as shown in FIG. 15, the core substrate 112 provided with the first outer insulation layer 120 turns over, and then the tape 114 is removed therefrom, and then a cooling member 124 connecting with the inner circuit layers 110 is adhered to the other side of the electronic component using a conductive material 122, for example, a conductive adhesive.

Subsequently, as shown in FIG. 16, a second outer insulation layer 126 is formed on the core substrate 112 provided with the cooling member 124. In this case, since the second outer insulation layer 126 is formed in the same manner as the first outer insulation layer 120, the detailed description thereof will be omitted.

Meanwhile, as shown in FIG. 17, outer circuit layers 130 connecting with the inner circuit layers 110 and/or pads 118 through vias 128 may be formed on the first outer insulation layer 120 and the second outer insulation layer 126. In this case, the vias 128 are formed to connect the pads 118, which are not connected to the inner circuit layers 110, or the inner circuit layers 110 to the outer circuit layers 130. These vias 128 are formed using a mechanical drill or a laser drill (CO₂ laser drill or Nd-YAG laser drill) or through a wet etching process.

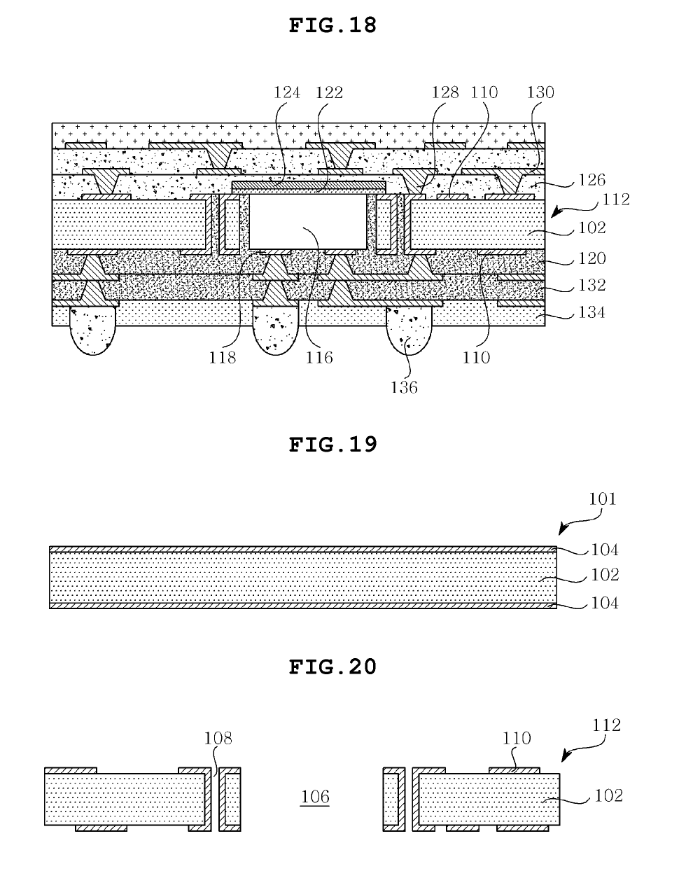

Moreover, as shown in FIG. 18, a build-up layer 132 including the insulation layers and circuit layers may be formed, a solder resist layer 134 for protecting the circuit layers may be formed on the outermost layer of the build-up layer 132, and solder balls 136 connecting with external appliances may be provided in the solder resist layer 134.

FIGS. 19 to 26 are sectional views showing a method of manufacturing an electronic component-embedded printed circuit board provided with a cooling member according to a second embodiment of the present invention. Hereinafter, this method of manufacturing an electronic component-embedded printed circuit board will be described with reference to FIGS. 19 to 26 as follows. In this embodiment, unlike the first embodiment, the electronic component-embedded printed circuit board is manufactured by mounting an electronic component in a printed circuit board so that it faces down. Meanwhile, in the description of this embodiment, the same reference numerals are used for those constituents which are the same as or correspond to those of the first embodiment, and the duplicate description thereof will be omitted.

First, as shown in FIG. 19, a base substrate 101, which is composed of a copper clad laminate (CCL) in which an insulation layer 102 is coated on both sides thereof with copper foil 104, is provided.

Subsequently, as shown in FIG. 20, a core substrate 112 is fabricated by forming a cavity 106 and through-holes 108 in the base substrate 101 and then forming inner circuit layers 110 thereon.

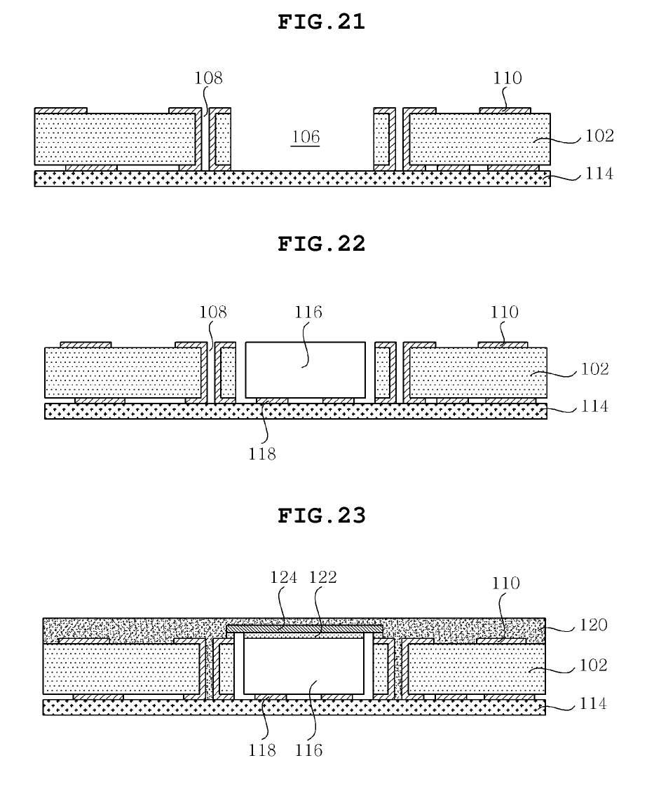

Subsequently, as shown in FIG. 21, a tape 114 for supporting an electronic component is adhered to one side of the core substrate 112.

Subsequently, as shown in FIG. 22, an electronic component 116 is mounted in the cavity 106 in a face-down manner such that pads 118 formed on one side of the electronic component 116 are adhered to the tape 114 formed one side of the core substrate 112. Here, ground pads 118a (refer to FIG. 9) may be formed on the other side of the electronic component 116.

Subsequently, as shown in FIG. 23, a cooling member 124 connecting with the inner circuit layers 110 is adhered to the other side of the electronic component using a conductive material 122, and a first outer insulation layer 120 is formed on the other side of the core substrate 112 provided with the cooling member 124. In this case, the first outer insulation layer 120 is formed on the other side of the core substrate 112 and in the through-holes 108.

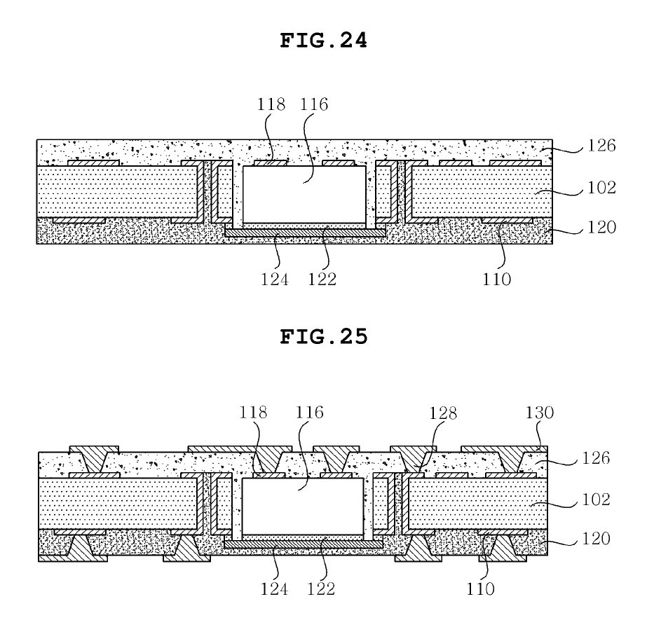

Subsequently, as shown in FIG. 24, the core substrate 112 provided with the first outer insulation layer 120 is turned over, and then the tape 114 is removed therefrom, and then a second outer insulation layer 126 is formed on the core substrate 112 and in the space between the electronic component 116 and the cavity 106.

Meanwhile, as shown in FIG. 25, outer circuit layers 130 connecting with the inner circuit layers 110 and/or pads 118 through vias 128 may be formed on the first outer insulation layer 120 and the second outer insulation layer 126.

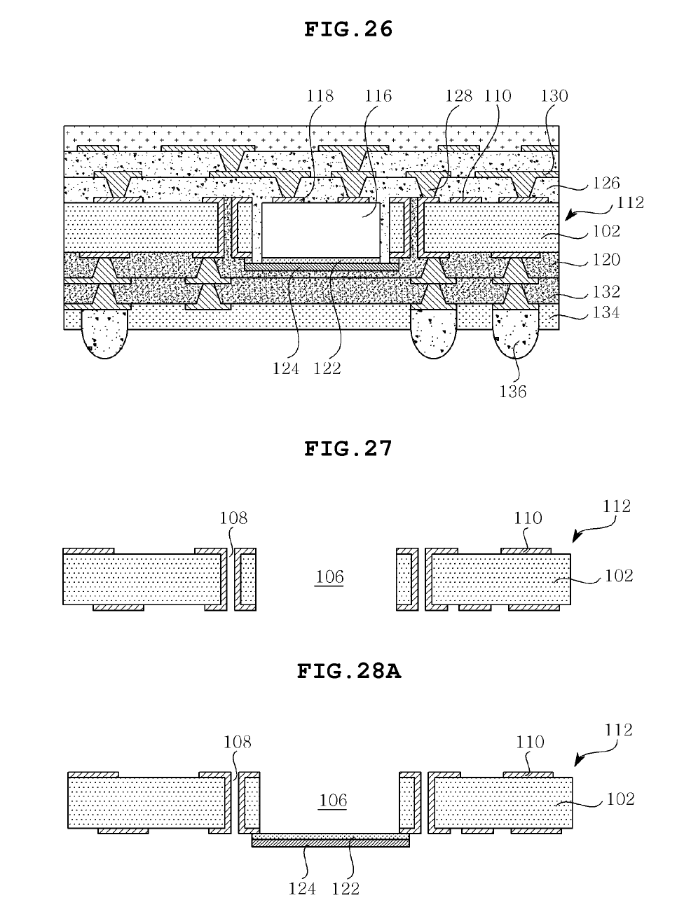

Moreover, as shown in FIG. 26, a build-up layer 132 including the insulation layers and circuit layers may be formed, a solder resist layer 134 for protecting the circuit layers may be formed on the outermost layer of the build-up layer 132, and solder balls 136 connecting with external appliances may be provided in the solder resist layer 134.

FIGS. 27 to 32 are sectional views showing a method of manufacturing an electronic component-embedded printed circuit board provided with a cooling member according to a third embodiment of the present invention. Hereinafter, this method of manufacturing an electronic component-embedded printed circuit board will be described with reference to FIGS. 27 to 32 as follows. This embodiment relates to an electronic component-embedded printed circuit board in which a cooling member is directly used to fix an electronic component instead of using an additional tape and outer insulation layers are simultaneously formed. Meanwhile, in the description of this embodiment, the same reference numerals are used for those constituents which are the same as or correspond to those of the first embodiment, and the duplicate description thereof will be omitted.

First, as shown in FIG. 27, a core substrate 112 is fabricated by forming a cavity 106 and through-holes 108 in a base substrate 101 and then forming inner circuit layers 110 thereon.

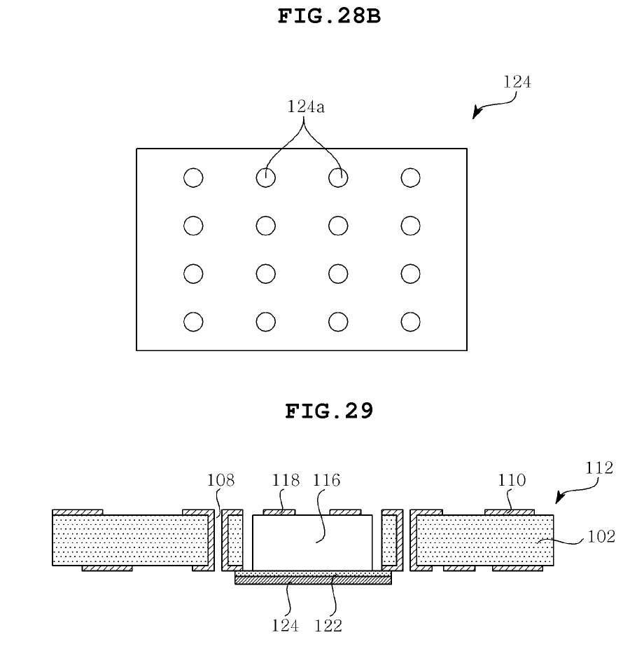

Subsequently, as shown in FIG. 28A, a cooling member 124 connecting with the inner circuit layers 110 is adhered to one side of the core substrate 112 using a conductive material 122 to cover the cavity 106.

In this case, since the cooling member 124 functions as a support layer, it is not required to additionally use a tape.

Meanwhile, it is preferred that the cooling member 124 be provided therein with holes 124 in order to prevent a void trap from occurring when the outer insulation layers 125 are pressurized (refer to FIG. 28B).

Subsequently, as shown in FIG. 29, an electronic component 116 is mounted on the cooling member 124 so as to face-up.

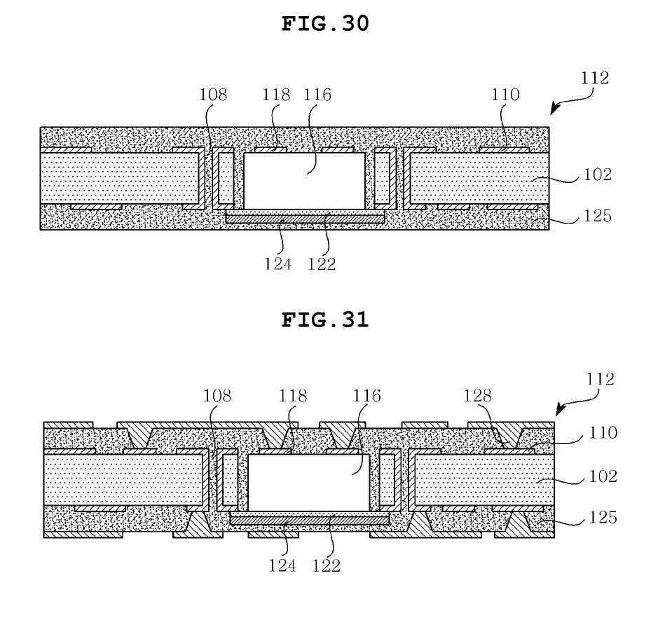

Subsequently, as shown in FIG. 30, outer insulation layers 125 are simultaneously pressurized and laminated on both sides of the core substrate 112 and in the through-holes 108 and the space between the electronic component 116 and the cavity 106.

Subsequently, as shown in FIG. 31, outer circuit layers 130 connecting with the inner circuit layers 110 and/or pads 118 through vias 128 are formed on the outer insulation layers 125.

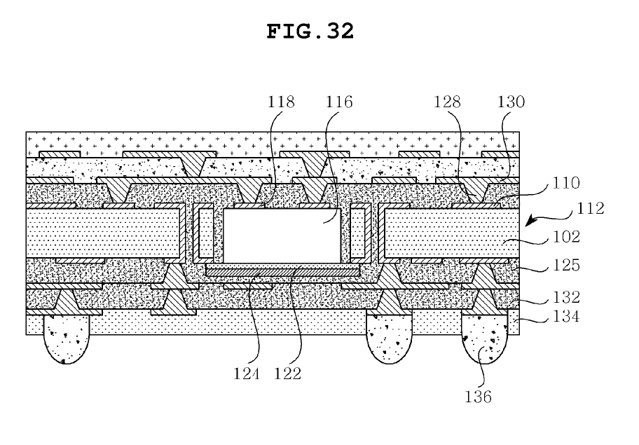

Moreover, as shown in FIG. 32, a build-up layer 132 including the insulation layers and circuit layers may be formed, a solder resist layer 134 for protecting the circuit layers may be formed on the outermost layer of the build-up layer 132, and solder balls 136 connecting with external appliances may be provided in the solder resist layer 134.

As described above, according to the electronic component-embedded printed circuit board of the present invention, since a cooling member is mounted in the printed circuit board in a state in which it is adhered to one side of an electronic component, the heat radiation performance thereof can be improved and the thickness thereof can be decreased.

Further, according to the electronic component-embedded printed circuit board of the present invention, since a cooling member is connected with inner circuit layers, the heat radiation performance thereof can be further improved

Further, the present invention provides a method of manufacturing an electronic component-embedded printed circuit board, which can use a conventional process of manufacturing an electronic component-embedded printed circuit board.

Further, according to the electronic component-embedded printed circuit board of the present invention, a cooling member is adhered to ground pads in a state in which the ground pads are formed on one side of an electronic component, and the cooling member is connected with inner circuit layers serving as ground layers, so that the heat radiation performance of the printed circuit board is improved, an additional structure for connecting the ground pads and the inner circuit layers is not required, and the densification of the printed circuit board can be increased.

Furthermore, according to the electronic component-embedded printed circuit board of the present invention, since holes are formed in a cooling member, it is possible to prevent a void trap from occurring when the outer insulation layers are formed.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

Simple modifications, additions and substitutions of the present invention belong to the scope of the present invention, and the specific scope of the present invention will be clearly defined by the appended claims.

What is claimed is:

1. An electronic component-embedded printed circuit board, comprising:
a core substrate in which a cavity is formed, and of which inner circuit layers are formed;
an electronic component which is mounted in the cavity and is provided on one side thereof with pads;
a cooling member which is adhered to the other side of the electronic component through a conductive material and is connected to the inner circuit layers; and
outer insulation layers which are formed on both sides of the core substrate to cover the electronic component.

2. The electronic component-embedded printed circuit board according to claim 1, wherein outer circuit layers connecting with the pads or the inner circuit layers through vias are formed on the outer insulation layers.

3. The electronic component-embedded printed circuit board according to claim 1, wherein the electronic component is formed on the other side thereof with ground pads, and the ground pads are connected with the cooling member through the conductive material.

4. The electronic component-embedded printed circuit board according to claim 1, wherein the inner circuit layers connected with the cooling member serve as ground layers.

5. The electronic component-embedded printed circuit board according to claim 1, wherein the conductive material is a conductive paste or a conductive adhesive.

6. The electronic component-embedded printed circuit board according to claim 1, wherein the cooling member is formed therein with holes.

7. A method of manufacturing an electronic component-embedded printed circuit board, comprising:
fabricating a core substrate provided with a cavity and inner circuit layers and then adhering a tape to one side of the core substrate;
adhering an electronic component provided on one side thereof with pads onto the tape such that the electronic component is mounted in the cavity so as to face-up;
forming a first outer insulation layer on the other side of the core substrate including a space between the electronic component and the cavity and then removing the tape; and
adhering a cooling member connecting with the inner circuit layers onto the other side of the electronic component using a conductive material and then forming a second outer insulation layer on the other side of the core substrate provided with the cooling member.

8. The method of manufacturing an electronic component-embedded printed circuit board according to claim 7, further comprising:
forming outer circuit layers connecting with the inner circuit layers or the pads through vias on the first outer insulation layer and the second outer insulation layer, after the forming of the second outer insulation layer.

9. The method of manufacturing an electronic component-embedded printed circuit board according to claim 7, wherein the electronic component is formed on the other side thereof with ground pads, and the ground pads are connected with the cooling member through the conductive material.

10. The method of manufacturing an electronic component-embedded printed circuit board according to claim 7, wherein the inner circuit layers connected with the cooling member serve as ground layers.

11. The method of manufacturing an electronic component-embedded printed circuit board according to claim 7, wherein the conductive material is a conductive paste or a conductive adhesive.

12. A method of manufacturing an electronic component-embedded printed circuit board, comprising:
fabricating a core substrate provided with a cavity and inner circuit layers and then adhering a tape to one side of the core substrate;
adhering an electronic component provided on one side thereof with pads onto the tape such that the electronic component is mounted in the cavity so as to face-down;
adhering a cooling member connecting with the inner circuit layers onto the other side of the electronic component using a conductive material and then forming a first outer insulation layer on the side of the core substrate provided with the cooling member; and
removing the tape and then forming a second outer insulation layer on the other side of the core substrate including a space between the electronic component and the cavity.

13. The method of manufacturing an electronic component-embedded printed circuit board according to claim 12, further comprising:
forming outer circuit layers connecting with the inner circuit layers or the pads through vias on the first outer insulation layer and the second outer insulation layer, after the forming of the second outer insulation layer.

14. The method of manufacturing an electronic component-embedded printed circuit board according to claim 12, wherein the electronic component is formed on the other side thereof with ground pads, and the ground pads are connected with the cooling member through the conductive material.

15. The method of manufacturing an electronic component-embedded printed circuit board according to claim 12, wherein the inner circuit layers connected with the cooling member serve as ground layers.

16. The method of manufacturing an electronic component-embedded printed circuit board according to claim 12, wherein the conductive material is a conductive paste or a conductive adhesive.

17. A method of manufacturing an electronic component-embedded printed circuit board, comprising:
fabricating a core substrate provided with a cavity and inner circuit layers and then adhering a cooling member to the inner circuit layer of one side of the core substrate to cover the cavity;
placing an electronic component provided on one side thereof with pads onto the cooling member such that the electronic component is mounted in the cavity so as to face-up; and
forming outer insulation layers on both sides of the core substrate including a space between the electronic component and the cavity.

18. The method of manufacturing an electronic component-embedded printed circuit board according to claim 17, wherein the cooling member is formed therein with holes.
